(19) United States
(12) Patent Application Publication
(10) Pub. No.: US 2010/0102370 A1
(43) Pub. Date: Apr. 29, 2010

(54) NON-VOLATILE MEMORY DEVICE AND METHOD OF MANUFACTURING NON-VOLATILE MEMORY DEVICE

(75) Inventor: Hiroyuki KANAYA, Kanagawa-ken (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/650,901

(22) Filed: Dec. 31, 2009

Related U.S. Application Data
(62) Division of application No. 11/943,212, filed on Nov. 20, 2007.

(30) Foreign Application Priority Data
Nov. 28, 2006 (JP) 2006-320197

(51) Int. Cl. H01L 27/115

(52) U.S. Cl. 257/295; 257/E27.104

(57) ABSTRACT

A non-volatile memory device including a ferroelectric capacitor is disclosed. A method of manufacturing a non-volatile memory device including a ferroelectric capacitor is also disclosed. A first electrode is formed on an insulating film provided on a semiconductor substrate. A first ferroelectric film is formed on the first electrode. The first ferroelectric film has a convexo-concave surface portion. A second ferroelectric film is formed on the first ferroelectric film so as to bury the convexo-concave surface portion. The second ferroelectric film has a surface flatter than that of the first ferroelectric film. A second electrode is formed on the second ferroelectric film. A protective film is formed at least on a portion of an upper surface of the second electrode. The protective film serves as a barrier against hydrogen.

### CROSS REFERENCE TO RELATED APPLICATION

This application is based upon and claims the benefit of priority from the prior Japanese Patent Application No. 2006-320197, filed on Nov. 28, 2006, the entire contents of which are incorporated herein by reference.

### FIELD OF THE INVENTION

The present invention relates to a non-volatile memory device including a ferroelectric capacitor and to a method of manufacturing a non-volatile memory device including a ferroelectric capacitor.

### DESCRIPTION OF THE BACKGROUND

Recent years, non-volatile memory devices have been developed which use ferroelectric material for insulating films of capacitors. Representative ferroelectric materials are lead zirconate titanate (PZT: PbZr_{X}Ti_{1-X}O₃) or bismuth strontium tantalite (SBT: SrBi₂Ta₂O₉), for example. Such non-volatile memory devices are attractive because of their advantages of high speed performance and low power consumption.

The ferroelectric material is basically a metal-oxide. The metal-oxide is apt to be reduced easily. When the metal-oxide is exposed to a strongly reducible gas such as hydrogen, it shows inferior characteristics and lowers reliability of the ferroelectric capacitors.

In order to avoid the problem, conventionally, an insulating protective film such as an aluminum-oxide film is coated on the ferroelectric capacitor. The insulating protective film is effective to block hydrogen.

Usually, a ferroelectric film is formed by MOCVD (Metal Organic Chemical Vapor Deposition) method. The ferroelectric film formed by the MOCVD is dense and shows preferable ferroelectric characteristics. But, flatness of the upper surface of the ferroelectric film is inferior due to its high orientation nature. The upper surface portion of the ferroelectric film has convexes and concaves.

When flatness of the upper surface of the ferroelectric film is inferior, flatness of an upper electrode, which is formed on the ferroelectric film, is also bad. In a case that a conductive hydrogen barrier film such as a titanium nitride film is formed on the convexo-concave upper electrode before a contact plug such as a tungsten (W) film is formed, coverage of the conductive hydrogen barrier film lowers. The thickness of the conductive hydrogen barrier film is locally small due to the inferior coverage. It causes lowering the hydrogen blocking capability of the conductive hydrogen barrier film.

An improved device and method for raising step coverage of a conductive hydrogen barrier film is discloses in Japanese Patent Application Publication (Kokai) No. 2006-32734 or No. 2005-340424.

The former publication shows a ferroelectric capacitor which has an upper electrode formed on a ferroelectric film having a convexo-concave surface. The upper surface of the upper electrode becomes flatter than the upper surface of the ferroelectric film by removing the upper portion of the upper electrode using an etch-back method or CMP (Chemical Mechanical Polishing) method.

However, the ferroelectric capacitor shown in the former publication is apt to lower its reliability, due to mechanical damages which are caused by removing the convexo-concave surface mechanically.

The latter publication shows a ferroelectric capacitor which has an upper electrode formed on a ferroelectric film having a convexo-concave surface. On the upper electrode, a conductive film is formed which has a melting point lower than the upper electrode. The upper surface of the conductive film becomes flatter than the upper surface of the upper electrode by re-flowing the upper surface of the conductive film with heat treatment.

However, the ferroelectric capacitor shown in the latter publication uses aluminum (Al) as a conductive film having a melting point lower than the upper electrode so that its reliability is likely to lower due to oxidation of aluminum.

### SUMMARY OF THE INVENTION

According to an aspect of the invention, a non-volatile memory device is provided, which comprises a semiconductor substrate, an insulating film formed on the semiconductor substrate, a first electrode formed on the insulating film, a first ferroelectric film formed on the first electrode, the first ferroelectric film having a convexo-concave surface portion, a second ferroelectric film formed on the first ferroelectric film to bury the convexo-concave surface portion, the second ferroelectric film having a surface flatter than that of the first ferroelectric film, a second electrode formed on the second ferroelectric film and connected to an interconnection, a protective film serving as a barrier against hydrogen and formed at least on an upper surface of the second electrode, and an insulated gate type transistor provided in connection with the semiconductor substrate, the insulated gate type transistor having a first diffusion layer connected to a bit line, a second diffusion layer connected to the first electrode and a gate electrode connected to a word line, wherein the first electrode, the first and second ferroelectric film and the second electrode constitute a ferroelectric capacitor.

According to another aspect of the invention, a non-volatile memory device is provided, which comprises a semiconductor substrate, an insulating film formed on the semiconductor substrate, a first electrode formed on the insulating film, a ferroelectric film formed on the first electrode and having a convexo-concave surface portion, a second electrode formed on the ferroelectric film and connected to an interconnection, the second electrode burying the convexo-concave surface portion and having a surface flatter than that of the ferroelectric film, a protective film serving as a barrier against hydrogen and formed at least on a surface of the second electrode, and an insulated gate type transistor provided in connection with the semiconductor substrate, the insulated gate type transistor having a first diffusion layer connected to a bit line, a second diffusion layer connected to the first electrode and a gate electrode connected to a word line, wherein the first electrode, the ferroelectric film and the second electrode constitute a ferroelectric capacitor.

According to further another aspect of the invention, a method of manufacturing a non-volatile memory device including a ferroelectric capacitor is provided, which comprises forming an insulating film on a substrate, forming a first electrode on the insulating film, forming a first ferroelectric film on the first electrode by a MOCVD method, forming a second ferroelectric film on the first ferroelectric film by a sol-gel method, forming a second electrode on the second ferroelectric film, and forming a protective film serving as a barrier against hydrogen at least on a portion of an upper surface of the second electrode.

According to yet another aspect of the invention, a method of manufacturing a non-volatile memory device including a ferroelectric capacitor is provided, which comprises forming an insulating film on a substrate, forming a first electrode on the insulating film, forming a ferroelectric film on the first electrode by a MOCVD method, forming a second electrode on the ferroelectric film by a sol-gel method, and forming a protective film serving as a barrier against hydrogen at least on a portion of an upper surface of the second electrode.

### BRIEF DESCRIPTION OF THE DRAWINGS

FIG. 1 is a cross-sectional view showing a main portion of a first embodiment of a non-volatile memory device according to the present invention.

FIG. 2A is a circuit diagram showing an example of a non-volatile memory cell.

FIG. 2B is a block diagram showing an example of a non-volatile memory device.

FIGS. 3 to 10 are cross-sectional views showing manufacturing steps of the first embodiment of the non-volatile memory device according to the present invention respectively.

FIG. 11 is a cross-sectional view showing a main portion of a second embodiment of a non-volatile memory device according to the present invention.

FIGS. 12 to 14 are cross-sectional views showing manufacturing steps of the second embodiment of the non-volatile memory device according to the present invention respectively.

FIG. 15 is a cross-sectional view showing a main portion of a third embodiment of a non-volatile memory device according to the present invention.

### DETAILED DESCRIPTION OF THE INVENTION

Embodiments of the present invention will be described hereinafter with reference to the accompanying drawings.

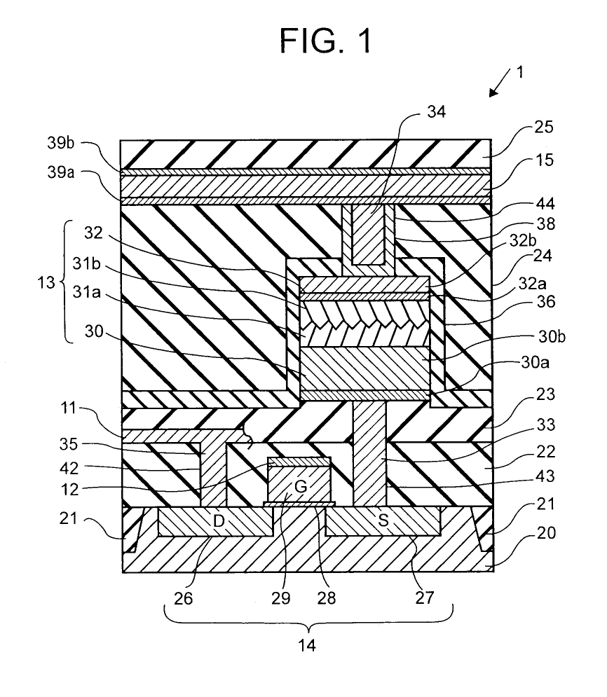

A first embodiment of a non-volatile memory device according to the invention will be described with reference to FIG. 1. FIG. 1 is a cross-sectional view showing a main portion of the first embodiment of the non-volatile memory device according to the invention.

As shown in FIG. 1, an element isolating layer 21 is formed on a semiconductor substrate 20, for example, a silicon substrate. An insulated gate type transistor 14 (called as “Cell Transistor”) is formed in a region surrounded by the element isolating layer 21.

The insulated gate type transistor 14 has a drain diffusion layer 26 as a first diffusion layer, a source diffusion layer 27 as a second diffusion layer, a gate insulating film 28 and a gate electrode 29 formed on the gate insulating film 28. The drain diffusion layer 26 and the source diffusion layer 26 are formed apart from each other in the semiconductor substrate 20. The gate insulating film 28 and the gate electrode 29 cover a semiconductor surface region between the drain diffusion layer 26 and the source diffusion layer 26.

An interlayer isolating layer 22 of TEOS (Tetra Ethyl Ortho Silicate: Si(OC₂H₅)₄), for example, is formed on a semiconductor substrate 20. A via hole 42 is provided in the interlayer isolating layer 22. A plug 35 is formed in the via hole 42. The plug 35 is connected to a bit line 11 which extends on and along the interlayer isolating layer 22.

A word line 12 is formed on the gate electrode 29. The side walls of word line 12 and the gate electrode 29 are coated with a side wall insulating film (not shown). An interlayer isolating layer 23 is formed on the interlayer isolating layer 22. A contact hole 43 is provided in the interlayer isolating layers 22, 23. A plug 33 of tungsten (W), for example, is formed in the contact hole 43 as a first contact plug.

A titanium aluminum nitride layer 30a of a 30 nm thickness, for example, is formed on the interlayer isolating layer 23 to contact with the plug 33. An iridium layer 30b of a 120 nm thickness, for example, is formed on the titanium aluminum nitride layer 30a. The titanium aluminum nitride layer 30a and the iridium layer 30b constitute laminated films (Ir/TiAlN) to form a lower electrode 30 as a first contact plug.

A first ferroelectric film 31a is formed on the lower electrode 30. The first ferroelectric film 31a is a lead zirconate titanate (PZT: PbZr_{X} Ti_{1-X}O₃), for example, and has convexes and concaves on its surface portion. On the first ferroelectric film 31a, a second ferroelectric film 31b is formed. The second ferroelectric film 31b is a lead zirconate titanate (PZT: PbZr_{X} Ti_{1-X}O₃), for example. The second ferroelectric film 31b buries the convexes and concaves of the first ferroelectric film 31a, and has an upper surface flatter than that of the first ferroelectric film 31a.

On the second ferroelectric film 31b, a strontium ruthenium oxide layer 32a of a 10 nm thickness, for example, is formed. An iridium oxide layer 32b of a 70 nm thickness, for example, is formed on the strontium ruthenium oxide layer 32a. The strontium ruthenium oxide layer 32a and the iridium oxide layer 32b constitute laminated films (IrO₂/SrRuO₃) to form an upper electrode 32 as a second contact plug.

The lower electrode 30, the first and second ferroelectric film 31a, 31b and the upper electrode 32 constitute a ferroelectric capacitor 13. An insulating protective film 36, which serves as a barrier against hydrogen, is formed on a surface of the second electrode 32, i.e. on an upper surface, on a side surface of the ferroelectric capacitor 13 and on the interlayer insulating film 23. The insulating protective film 36 is aluminum oxide (Al₂O₃), for example. Adjacently to the insulating protective film 36, an interlayer insulating film 24, for example, a TEOS film is formed in an atmosphere containing hydrogen to bury the ferroelectric capacitor 13.

A contact hole 44 is formed in the insulating protective film 36 and the interlayer insulating film 24. A conductive protective film 38, for example, a titanium nitride (TiN) film is formed in the contact hole 44. The conductive protective film 38 is in contact with the iridium oxide layer 32b. In the contact hole 44, a plug 34 of tungsten (W), for example, is formed in an atmosphere containing hydrogen. The plug 34 serves as a second contact plug.

A barrier metal film 39a such as a titanium nitride (TiN) film is formed on the interlayer insulating film 24. The barrier metal film 39 is in contact with the plug 34 and serves as a barrier against hydrogen. On the barrier metal film 39a, a common interconnection 15 is formed. A power source voltage is to be supplied to the common interconnection 15. On the common interconnection 15, a barrier metal film 39b such as a titanium nitride (TiN) film is formed. The barrier metal film 39b serves as a barrier against hydrogen.

The insulated gate type transistor 14, the ferroelectric capacitor 13 and the interconnections constitute a non-volatile memory cell 1.

The first ferroelectric film 31a constituting the ferroelectric capacitor 13 is formed by a MOCVD which is dense and has an about 70 nm thickness and high ferroelectric characteristics. The first ferroelectric film 31a formed by the MOCVD is polycrystalline and shows high orientation nature so that convexes and concaves are produced on its upper surface portion. The convexes and concaves have heights ranging from about 35 nm to about 105 nm.

The second ferroelectric film 31b is formed to have an about 50 nm thickness by a sol-gel method, for example. The second ferroelectric film 31b is formed by a sol-gel method using a spin-coating process, for example.

The lower surface portion of the second ferroelectric film 31b buries the convexes and concaves of the first ferroelectric film 31a. Convexes and concaves of the upper portion of the second ferroelectric film 31b may be within a 20 nm height, for example, which may provide the heights of the convexes and concaves below halves of those of the first ferroelectric film 31a. The upper surface of the second ferroelectric film 31b may be flatter than the upper surface of the first ferroelectric film 31.

The laminated structure of the first and second ferroelectric films 31a, 31b may provide a ferroelectric film having high ferroelectric characteristics and a flat upper surface.

The insulating protective film 36 suppresses that the first and second ferroelectric films 31a, 31b are reduced by reaction of TEOS and oxygen when an interlayer insulating film 24 is formed. The conductive protective film 38 suppresses that the first and second ferroelectric films 31a, 31b are reduced when the plug 34 of tungsten is formed in the hydrogen atmosphere.

According to the above first embodiment, the upper surface of the second ferroelectric films 31b is rendered flat so that step coverage of the insulating protective film 36 and the conductive protective film 38, which is formed on the upper electrode 32, is sufficient. The thicknesses of the insulating protective film 36 and the conductive protective film 38 are approximately uniform so that hydrogen blocking capability may be improved.

The heights of the convexes and concaves of the first and second ferroelectric films 31a, 31b are the differences of heights between the convexes and the concaves. The differences of heights mean values to be obtained by measuring an upper surface of a test piece formed under the same conditions as the first and second ferroelectric films 31a, 31b, using an AFM (Atomic Force Microscopy). The thicknesses of the first and second ferroelectric films 31a, 31b mean thicknesses from the average height values of the convexes and concaves of the surface portions to the other surfaces of the films 31a, 31b.

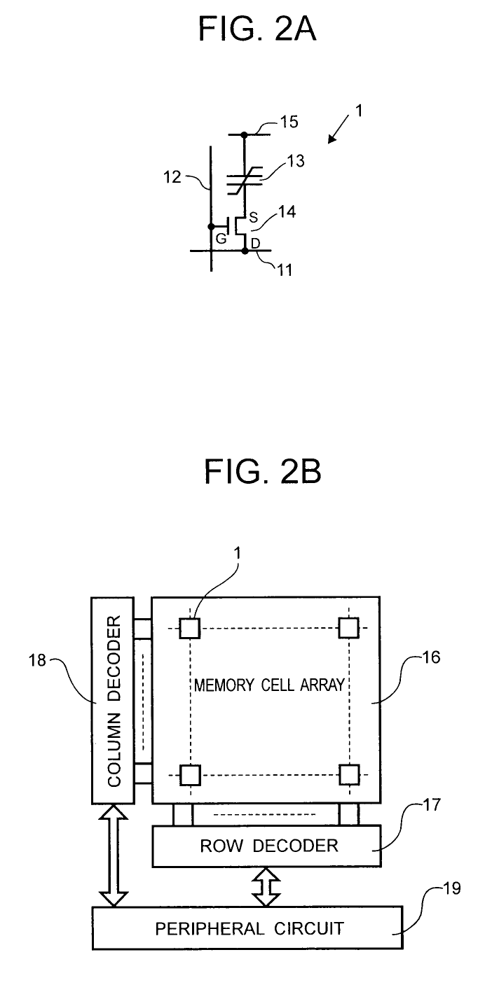

The non-volatile memory cell 1 explained with reference to FIG. 1 constitutes circuit shown in FIG. 2A. In FIG. 2A, one terminal of the ferroelectric capacitor 13 is connected to the source of the insulated gate type transistor 14. The other terminal of the ferroelectric capacitor 13 is connected to the common interconnection 15. The drain of the insulated gate type transistor 14 is connected to the bit line 11. The gate of the insulated gate type transistor 14 is connected to the word line 12.

FIG. 2B is a block diagram showing an example of the non-volatile memory device to be constituted by the non-volatile memory cells 1, . . . , 1. In a memory cell array 16, large numbers of the bit lines and the word lines are wired like a matrix. Each of the non-volatile memory cells 1, . . . , 1 is arranged approximately at a crossing point of each of the bit lines and each of the word lines.

A row decoder 17 and a column decoder 18 are arranged to select one of the non-volatile memory cells 1, . . . , 1 in the memory cell array 16. A peripheral circuit 19 is arranged to drive the row decoder 17 and a column decoder 18 and to write data being provided from outside into a selected one of the non-volatile memory cells 1, . . . , 1. The peripheral circuit 19 drives the row decoder 17 and a column decoder 18 to read out data from a selected one of the non-volatile memory cells 1, . . . , 1 to provide to outside.

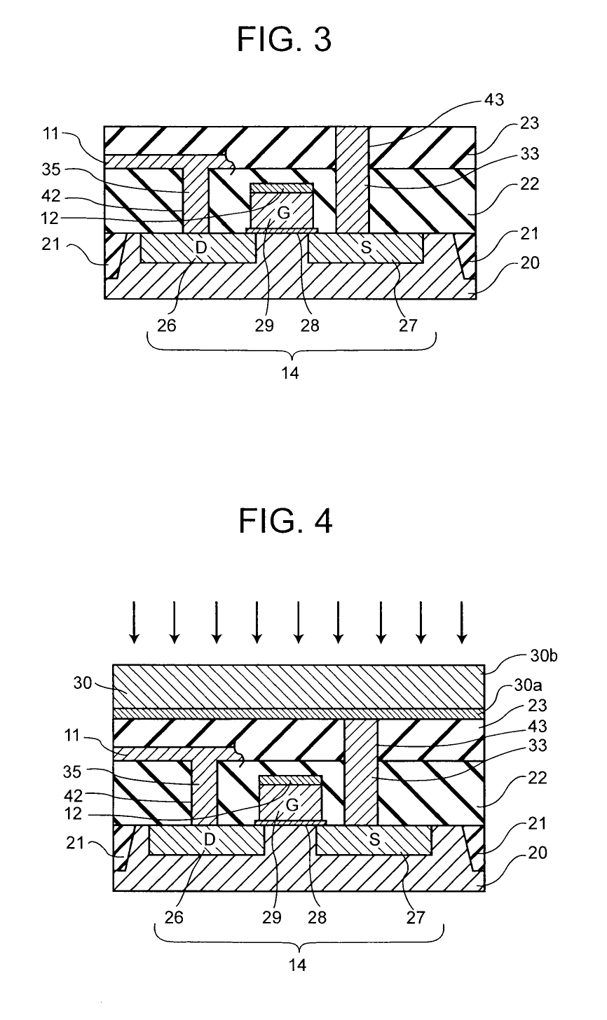

An example of a method of manufacturing the non-volatile memory device according to the first embodiment will be described with reference to FIG. 3 to FIG. 10.

FIGS. 3 to 10 are cross-sectional views showing manufacturing steps of the first embodiment respectively.

As shown in FIG. 3, a semiconductor substrate 20, for example, a P-type silicon substrate is prepared. A trench is formed in the semiconductor substrate 20. An element isolating layer 21 is formed by burying an insulating film such as a silicon dioxide film in the trench.

A silicon dioxide film is formed on the semiconductor substrate 20 by thermal oxidation. An impurity-doped poly-silicon film is formed on the silicon dioxide film by a CVD (Chemical Vapor Deposition) method. A gate insulating film 28 and a gate electrode 29 are formed by patterning the poly-silicon film and the silicon dioxide film using a photo-lithography method.

Impurities of a conductivity type opposite to that of the semiconductor substrate 20 are implanted into the semiconductor substrate 20 by an ion-implantation method. The impurities may be arsenic (As). As a result, a drain diffusion layer 26 and a source diffusion layer 27 are formed so that an insulated gate type transistor 14 (Cell Transistor) is formed.

A word line 12 is formed on the gate electrode 29. An interlayer insulating film 22 is formed on the semiconductor substrate 20 including the insulated gate type transistor 14 by a CVD method. A via hole 42 is formed in the interlayer insulating film 22. A plug 35 is formed in the via hole 42. A bit line 11 is formed on the interlayer insulating film 22 to connect the drain diffusion layer 26 to the bit line 11. Further, an interlayer insulating film 23 is formed on the entire surface.

A contact hole 43 is formed in the interlayer insulating films 22, 23. The contact hole 43 perforates the interlayer insulating films 22, 23 to reach the source diffusion layer 27. Tungsten is buried in the contact hole 43 by a CVD method and a CMP method to form a plug 33.

As shown in FIG. 4, a titanium aluminum nitride layer 30a of a 30 nm thickness, for example, is formed on the interlayer isolating layer 23 by a sputtering method. Further, an iridium layer 30b of a 120 nm thickness, for example, is formed on the titanium aluminum nitride layer 30a . The titanium aluminum nitride layer 30a and the iridium layer 30b constitute laminated films (Ir/TiAlN) to form a lower electrode 30.

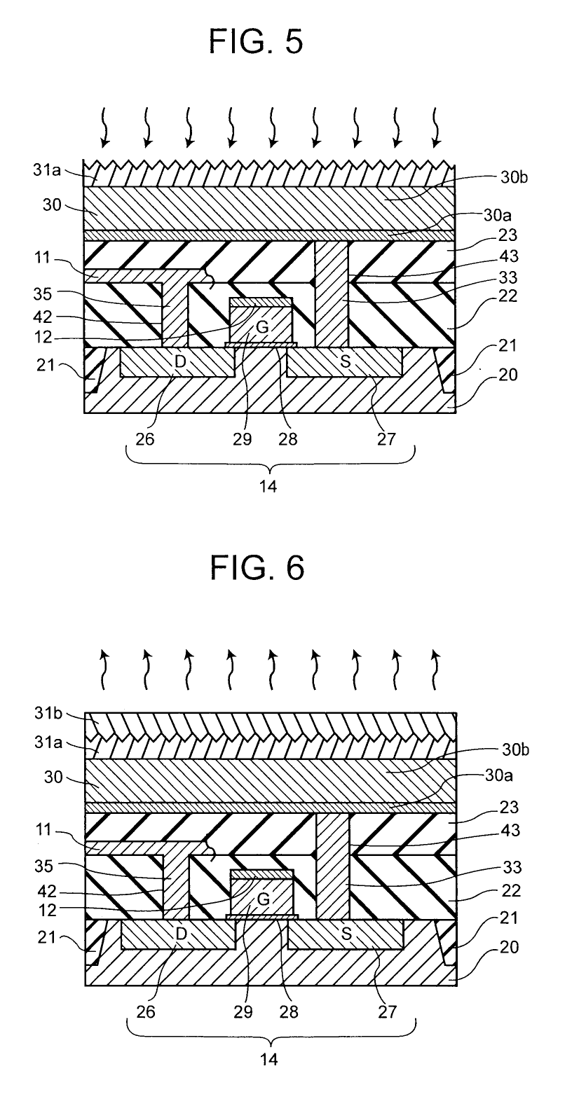

As shown in FIG. 5, a first ferroelectric film 31a of lead zirconate titanate (PZT) is formed on the lower electrode 30 by a MOCVD method. The first ferroelectric film 31a has a 70 nm thickness. The MOCVD method is carried out using three kinds of organic metal gases including (CHO_{X})Pb, (CHO_{X})Zr and (CHO_{X})Ti at a 600 to 630° C.

In order to form the first ferroelectric film 31a denser, it is preferable to perform a RTA (Rapid thermal annealing) in an oxygen atmosphere at 630° C., for example.

The first ferroelectric film 31a of lead zirconate titanate (PZT), which is formed by the MOCVD, is a poly-crystalline film having high orientation nature, dense and includes fewer holes. Thus, the first ferroelectric film 31a shows good ferroelectric characteristics. At the surface portion of the first ferroelectric film 31a, convexes and concaves of 35 to 105 nm heights are produced in the case the first ferroelectric film 31a is a 70 nm deposited film of PZT. The convexes and concaves are produced because differences of crystal growth speeds exist depending on crystalline surface orientation.

As shown in FIG. 6, a second ferroelectric film 31b is formed on the first ferroelectric film 31a by a sol-gel method which will be explained in detail below. The second ferroelectric film 31b is a lead zirconate titanate (PZT) and has a 50 nm thickness, for example. The second ferroelectric film 31b buries the convexes and concaves of the first ferroelectric film 31a, and has an upper surface flatter than that of the first ferroelectric film 31a.

In order to carry out the sol-gel method, a metal alkoxide is prepared which is expressed as M(OR)_{X}. where each of the metal ions of Zr, Ti and Pb is coupled to an alkyl group via an oxygen ion. Here, M is metal, O is oxygen, R is an alkyl group, and X is a valence number. The metal alkoxide is made by mixing ZrO₂, TiO₂ and Pb₂O₃ in a solvent such as polyethylene glycol, for example and by rendering reducing reaction under existence of alcohol.

A compound metal alkoxide solution as a preservative liquid is made by mixing the metal alkoxide of Zr, Ti and Pb in 2-methoxyethanol as a solvent with a voluntary mixing rate.

A polymer-like gel is obtained by adding water into the preservative liquid and by hydrolyzing the preservative liquid to cause condensation polymerization to form a precusor solution. As the gel solution, CFP-1 of Kanto Chemical Co., Inc. may be used. The nominal composition of Zr, Ti and Pb is following.

Zr:Ti:Pb=52:48:105

The obtained gel solution is dropped and coated onto the first ferroelectric film 31a. The coated gel film is dried by spin so that the solvent of the coated gel film is evaporated, and remaining organic functional group is combusted. The thickness of the film is adjusted by repeating the coating and the drying.

Ferroelectric characteristics of the coated film may be obtained by applying a RTA to the dried coated film at 550 to 650° C. in a oxygen atmosphere to densify and to crystallize the coated film. For example, in the case of CFP-1, a RTA is to be applied to the coated film at 650° C. in an oxygen atmosphere, after pre-baking the film at 450° C. in a oxygen atmosphere.

By the above processes, the second ferroelectric film 31b is completed which buries the first ferroelectric film 31a and has an upper surface flatter than that of the first ferroelectric film 31a. The heights of the convexes and concaves of the second ferroelectric film 31b may be flattened below halves of those of the first ferroelectric film 31a, for example.

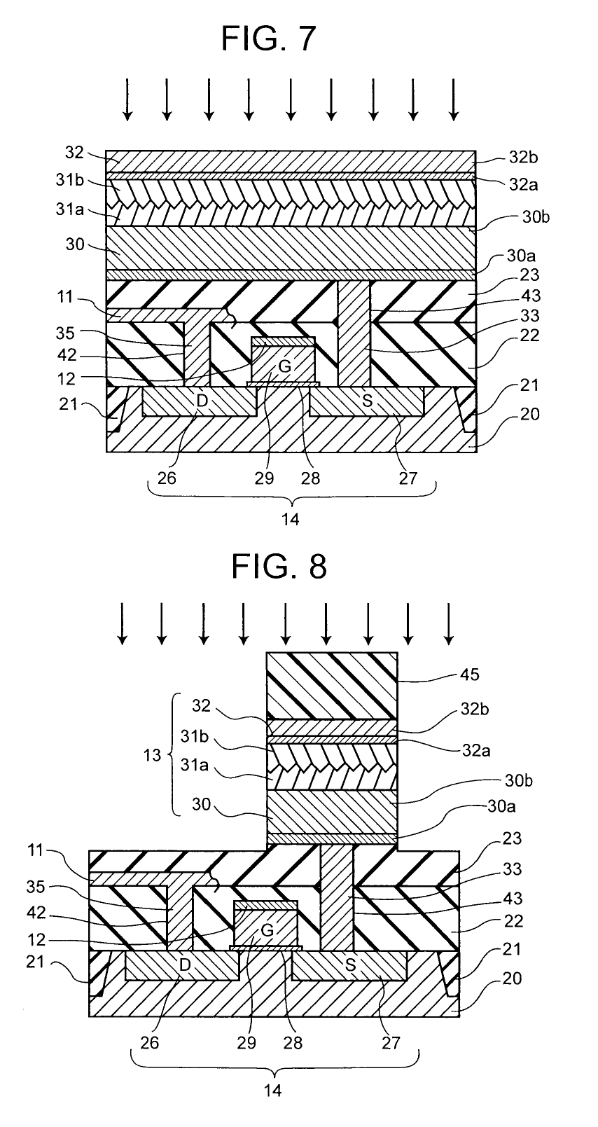

As shown in FIG. 7, on the second ferroelectric film 31b, a strontium ruthenium oxide layer 32a of a 10 nm thickness, for example, is formed by a sputtering method. An iridium oxide layer 32b of a 70 nm thickness, for example, is also formed on the strontium ruthenium oxide layer 32a by a sputtering method. The strontium ruthenium oxide layer 32a and the iridium oxide layer 32b constitute laminated films (IrO₂/SrRuO₃) to form an upper electrode 32.

The upper surface of the second ferroelectric film 31b is flattened so that the upper surface of the laminated films constituted by IrO₂/SrRuO₃ is also flat.

As shown in FIG. 8, a mask 45 of silicon dioxide is formed. The mask 45 has a about 440 nm width and is located at the position corresponding to that of a plug 34 to be formed later. The iridium oxide layer 32b, the strontium ruthenium oxide layer 32a, the second ferroelectric film 31b, the first ferroelectric film 31b, the iridium layer 30b and the titanium aluminum nitride layer 30a are etched one after another by a RIE method under existence of the mask 45.

By the process, a ferroelectric capacitor 13 is formed where the first and second ferroelectric films 31a, 31b are sandwiched between the lower and upper electrodes 30, 32. A surface portion of the interlayer insulating film 23 surrounding the ferroelectric capacitor 13 is slightly over-etched.

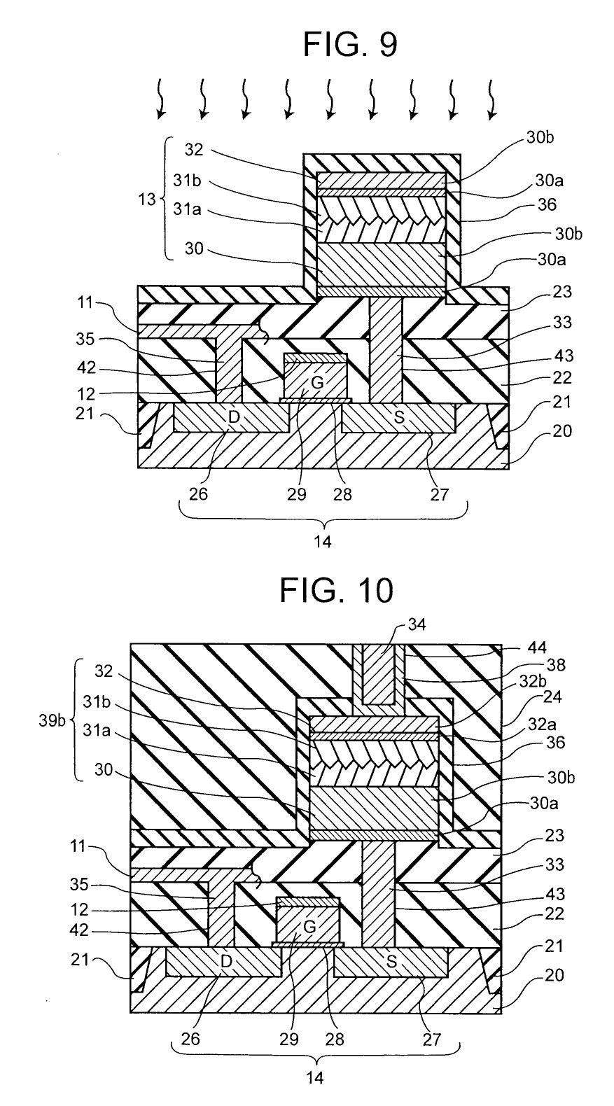

As shown in FIG. 9, after the mask 45 is removed, an aluminum oxide film as an insulating protective film 36, which serves as a barrier against hydrogen, is formed on the upper surface and the side surface of the ferroelectric capacitor 13 and on the interlayer insulating film 23. The aluminum oxide film has a 50 to 100 nm thickness and is produced by a sputtering method in a mixture gas of Argon (Ar) and oxygen (O₂).

The upper surface of the upper electrodes 32, which is formed on the second ferroelectric film 31b having the flat upper surface, step coverage of the insulating protective film 36 is good. Accordingly, it is possible to form the film 36 on the upper surface of the upper electrodes 32 with a uniform film thickness.

As shown in FIG. 10, an interlayer insulating film 24 is formed on the insulating protective film 36 by a CVD method in a hydrogen atmosphere. A contact hole 44 is formed by a RIE method. The contact hole 44 penetrates the interlayer insulating film 24 and the insulating protective film 36 and reaches the upper electrode 32.

A conductive protective film 38, for example, a titanium nitride (TiN) film is formed on the upper electrode 32 exposed to the contact hole 44 and on the inner surface of the contact hole 44 by a sputtering method. The conductive protective film 38 serves as a barrier against hydrogen.

As the upper surface of the upper electrodes 32, which is formed on the flat upper surface of the second ferroelectric film 31b, is flat, step coverage of the conductive protective film 38 is also sufficient. Accordingly, it is possible to form the film 38 with a uniform film thickness.

A plug 34 of tungsten (W) is formed in the contact hole 44 at 400° C. in an atmosphere containing hydrogen using a MOCVD method. When the tungsten is deposited in the process, hydrogen is produced. But, diffusion of the hydrogen is prevented to enter into the first and second ferroelectric film 31a, 31b by the conductive protective film 38.

A barrier metal film 39a of titanium nitride (TiN) film is formed on the interlayer insulating film 24. On the barrier metal film 39a, an aluminum film is formed. The aluminum film and the barrier metal film 39a are patterned to form a common interconnection 15. The obtained common interconnection 15 is coated by a barrier metal film 39b. Further, The entire surface is coated by an insulating film 25.

According to the above manufacturing method, the convexes and concaves are produced on the upper surface portion of the first ferroelectric film 31a in the MOCVD process. However, the second ferroelectric film 31b is formed by the sol-gel method to bury the convexes and concave of the upper surface portion of the first ferroelectric films 31a. As a result, the second ferroelectric film 31b has an upper surface flatter than that of the first ferroelectric film 31a.

Step coverage of the insulating protective film 36 and of the conductive protective film 38, which will be formed in the later steps, becomes sufficient so that the thicknesses of the films 36, 38 may be approximately uniform.

Thus, diffusion of hydrogen may be prevented to enter into the upper electrodes 32 and into the ferroelectric capacitor 13, during manufacture of the non-volatile memory device. Contact yield of the plug 34 is sufficient, and characteristic fluctuation of the non-volatile memory device is small, according to the above manufacturing method.

The Contact yield and the characteristic fluctuation of the non-volatile memory device may be much smaller, when the heights of the convexes and concaves of the upper surface of the upper electrodes 32 are below halves of those of the convexes and concaves of the first ferroelectric film 31a, i.e. within 40 nm, for example.

In the above embodiment, the first and second ferroelectric films 31a, 31b are lead zirconate titanate (PZT). Other ferroelectric material such as bismuth strontium tantalite (SBT) may be used.

The first and second ferroelectric films 31a, 31b may be other materials. For example, the first ferroelectric film 31a may be PZT, and the second ferroelectric films 31b may be SBT. The first ferroelectric film 31a may be SBT, and the second ferroelectric films 31b may be PZT.

The insulating protective film 36 may be titanium oxide, aluminum nitride or silicon nitride instead of aluminum oxide.

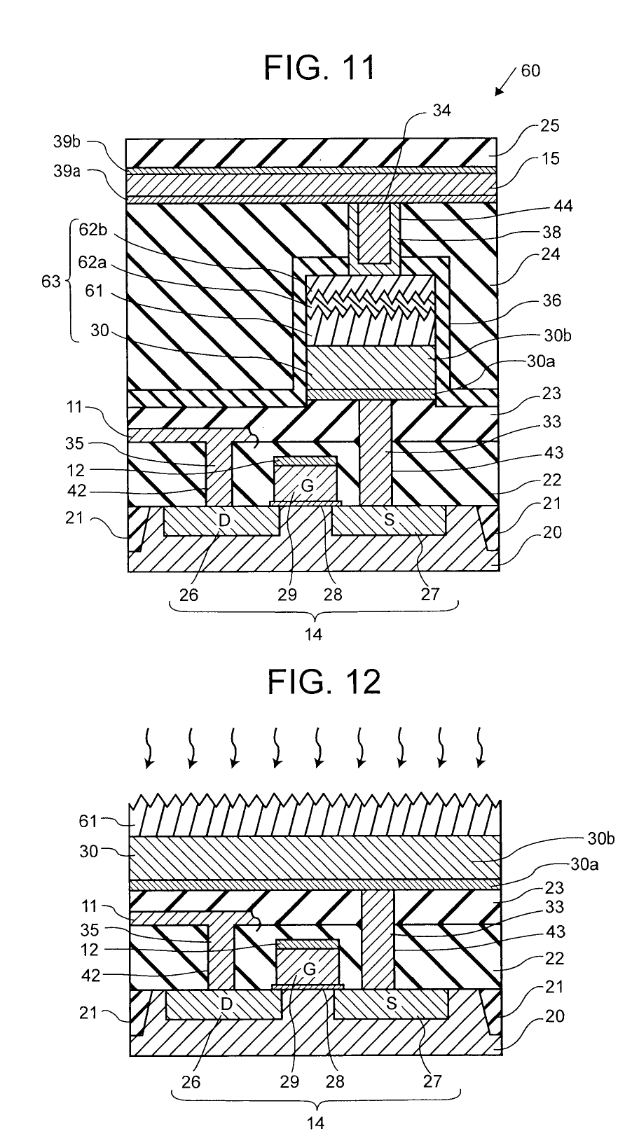

A second embodiment of the non-volatile memory device according to the invention will be described with reference to FIG. 11.

FIG. 11 is a cross-sectional view showing a main portion of the second embodiment of the non-volatile memory device according to the invention. In the following description of the second embodiment, the same constituents as those in the first embodiment are designated by the same reference numerals.

FIG. 11 shows a cross-section of a non-volatile memory cell 60. In FIG. 11, the lower electrode 30 as a first contact plug includes the titanium aluminum nitride layer 30a and the iridium layer 30b, which constitute the laminated films (Ir/TiAlN).

A ferroelectric film 61a is formed on the lower electrode 30. The ferroelectric film 61a has convexes and concaves on its upper surface. A first upper electrode 62a is formed on the ferroelectric film 61a. On the first upper electrode 62a, a second upper electrode 62b is formed. The second upper electrode 62b is flatter than the first upper electrode 62a. The lower electrode 30, the ferroelectric film 61 and the first and second upper electrode 62a, 62b constitute a ferroelectric capacitor 63.

The ferroelectric film 61 is a PZT film of approximately 100 nm thickness formed by a MOCVD method, for example. The ferroelectric film 61 has convexes and concaves on its upper portion. The convexes and concaves have 50 to 150 nm heights.

The first upper electrode 62a is, for example, a strontium ruthenium oxide (SrRuO₃) film of a 10 nm thickness formed by a sputtering method. The upper portion of the first upper electrode 62a has convexes and concaves corresponding to the convexes and concaves of the upper portion of the ferroelectric film 61.

The second upper electrode 62a is an iridium oxide (IrO₂) film of a 70 nm thickness formed by a sol-gel method, for example. The second upper electrode 62a buries the convexes and concaves of the upper portion of the ferroelectric film 61 and has an upper surface flatter than the ferroelectric film 61.

The insulating protective film 36 and the conductive protective film 38, which serve as barriers against hydrogen respectively, are formed on the side surface of the ferroelectric capacitor 63 and on the interlayer insulating film 23. As the upper surface of the second upper electrode 62b is flat, step coverage of the insulating protective film 36 and the conductive protective film 38 is sufficeint to raise capability of blocking hydrogen.

An example of a method of manufacturing the non-volatile memory device according to the second embodiment will be described with reference to FIGS. 12 to 14. FIGS. 12 to 14 are cross-sectional views showing manufacturing steps of the first embodiment of the non-volatile memory device according to the invention respectively.

In FIG. 12, the titanium aluminum nitride layer 30a is formed on the interlayer insulating film 23 by a sputtering method. The iridium layer 30b, is formed on the titanium aluminum nitride layer 30 by a sputtering method. The laminated films of Ir/TiAlN will be patterned to form a lower electrode in the later step. On the laminated films of Ir/TiAlN, a ferroelectric film 61 of PZT of an about 100 nm thickness is formed by a CVD method. Convexes and concaves of about 50 to 150 nm heights are produced on the upper portion of the ferroelectric film 61.

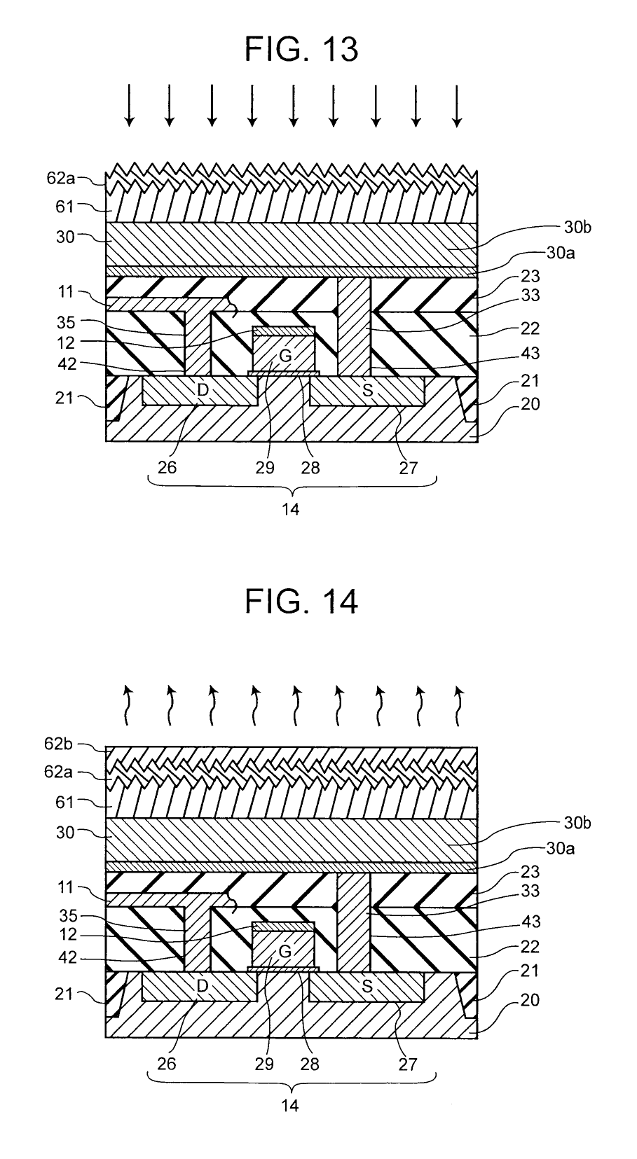

As shown in FIG. 13, a strontium ruthenium oxide (SrRuO₃) film 62a of a 10 nm thickness is formed by a sputtering method.

Convexes and concaves are produced on the upper surface of the strontium ruthenium oxide (SrRuO₃) film 62a. The convexes and concaves corresponds to those of the ferroelectric film 61 in height. The strontium ruthenium oxide (SrRuO₃) film 62a becomes a first upper electrode.

As shown in FIG. 14, an iridium oxide (IrO₂) film 62b of a 70 nm thickness is formed by a sol-gel method, which will be explained hereinafter.

The iridium oxide film 62b is formed to bury the convexes and concaves of the upper portion of the strontium ruthenium oxide film 62a so that the upper portion of the iridium oxide film 62b becomes flatter than that of the ferroelectric film 61.

In order to carry out the sol-gel method, an iridium alkoxide is prepared, which is expressed as M(OR)_{X}. Here, M is iridium, O is oxygen, R is an alkyl group, and X is a valence number. The iridium alkoxide is made by mixing iridium oxide (IrO₂) in a solvent such as polyethylene glycol and by rendering reducing reaction under existence of alcohol.

A polymer-like gel is obtained by adding water into the iridium alkoxide and by hydrolyzing the obtained liquid to cause condensation polymerization to form a precusor solution.

The obtained gel solution is dropped and coated onto the strontium ruthenium oxide film 62a. The coated film is dried by spin so that the solvent of the coated gel film is evaporated, and remaining organic functional group is combusted. The thickness of the film is adjusted by repeating the coating and the drying.

The dried coated film is preferably heat-treated at 500 to 600° C., for example, in a oxygen atmosphere to densify the film. A RTA may be carried out at 550° C. in an oxygen atmosphere, after the coated film is prebaked at 450° C. for 60 minutes in an oxygen atmosphere.

By the above process, the iridium oxide (IrO₂) film 62b is formed to bury the convexes and concaves of the upper portion of the strontium ruthenium oxide (SrRuO₃) film 62a. The upper surface of the iridium oxide film 62b may be flatter than that of the ferroelectric film 61. The iridium oxide film 62b is patterned to form the second upper electrode. Further, the strontium ruthenium oxide film 62a, the ferroelectric film 61, the titanium aluminum nitride layer 30a and the iridium layer 30b are patterned to form the ferroelectric capacitor 63 including the lower electrode 30, the ferroelectric film 61 and the first and second upper electrodes 62a, 62b shown in FIG. 11 respectively.

The heights of the convexes and concaves of the second upper electrodes 62b may be flattened below halves of those of the ferroelectric film 61.

The insulating protective film 36, which serves as a barrier against hydrogen, is formed on the upper surface of the second upper electrodes 62b, on the side surface of the ferroelectric capacitor 63 and on the interlayer insulating film 23 extendedly. After the step, the non-volatile memory cell 60 is formed by the same steps as those of the first embodiment of the invention.

The conductive protective film 38, which has hydrogen blocking characteristics, is formed to contact with the upper surface of the second upper electrodes 62b.

As the upper surface of the second upper electrode 62b is flat, step coverage of the insulating protective film 36 and the conductive protective film 38 is sufficient to raise capability of blocking hydrogen.

The upper surface of the second upper electrode 62b is formed on the first upper electrode 62a by the sol-gel method and is flatter than the upper surface of the ferroelectric film 61. As a result, step coverage of the insulating protective film 36 and the conductive protective film 38 is sufficient. Accordingly, it is possible to form the film 38 having a uniform film thickness.

Thus, the ferroelectric capacitor 61 may have good ferroelectric characteristics.

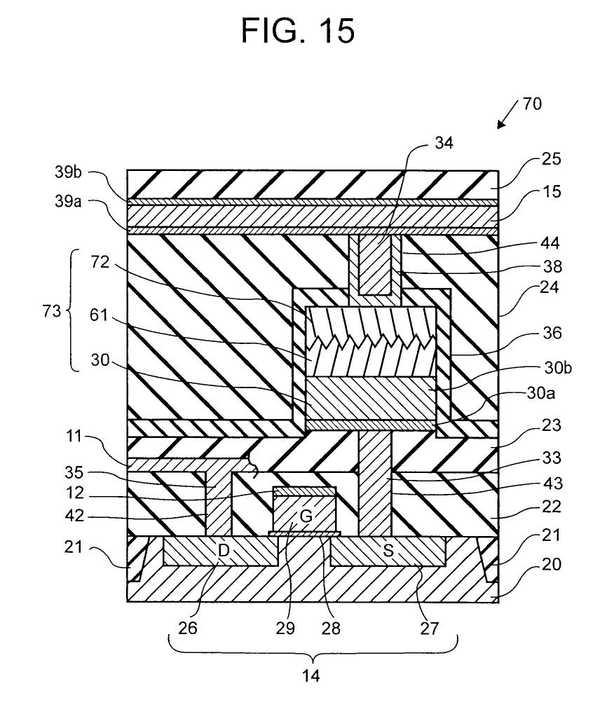

A third embodiment of the non-volatile memory device according to the invention will be described with reference to FIG. 15.

FIG. 15 is a cross-sectional view showing a main portion of the third embodiment of the non-volatile memory device according to the invention.

In the following description of the second embodiment, the same constituents as those in the first and second embodiments are designated by the same reference numerals.

FIG. 15 is a cross-sectional view of a non-volatile memory cell 70 of the non-volatile memory device.

In FIG. 15, the ferroelectric film 61 is formed on the lower electrode 30. The ferroelectric film 61 has convexes and concaves on its upper portion. An upper electrode 72 is formed on the ferroelectric film 61. The lower electrode 30, the ferroelectric film 61 and the upper electrode 72 constitute a ferroelectric capacitor 73.

The ferroelectric film 61 is a lead zirconate titanate (PZT: PbZr_{X} Ti_{1-X}O₃) film, for example, and has an about 100 nm thickness. The heights of the convexes and concaves of the ferroelectric film 61 are 50 to 150 nm. Such a ferroelectric film may be formed by a MOCVD method, for example. The MOCVD method is carried out at 600 to 630° C. using three kind of organic metal gases including (CHO_{X})Pb, (CHO_{X})Zr and (CHO_{X})Ti.

The upper electrode 72 may be an iridium oxide (IrO₂) film of an about 70 nm thickness. The upper electrode 72 may be formed by a sol-gel method, for example. In order to make the iridium oxide film f denser, it is preferable to perform a RTA (Rapid thermal annealing) at 600° C., for example in an oxygen atmosphere.

By using the sol-gel method, the convexes and concaves of the ferroelectric film 61 are buried by the lower portion of the upper electrode 72. The upper electrode 72 has an upper surface flatter than that of the ferroelectric film 61. The heights of the convexes and concaves of the upper electrodes 72 may be flattened below halves of those of the ferroelectric film 61.

The third embodiment has an advantage that the sol-gel process of forming the upper electrode 72 is easier to implement, in comparison with the first embodiment where the sol-gel method is performed using three kinds of metal alkoxide.

In the above described embodiments, the drain diffusion layer 26 and the source diffusion layer 27 are formed in apart from each other in the semiconductor substrate 20. The gate insulating film 28 and the gate electrode 29 are formed above the semiconductor surface region between the drain diffusion layer 26 and the source diffusion layer 27. Instead, a poly-silicon layer may be formed on the semiconductor substrate 20 to form an insulated gate type transistor in the poly-silicon layer. Further, in place of the semiconductor substrate 20, SOI (Silicon On Insulator) substrate or an insulating substrate with a poly-silicon layer formed may be used.

In the above described embodiments, diffusion of hydrogen may be prevented to enter into the ferroelectric films 31a, 31b or 61 by forming the insulating protective film 36 and the conductive protective film 38. Notwithstanding existence of the convexes and concaves of the ferroelectric film 31a, 31b or 61, step coverage of the insulating protective film 36 or the conductive protective film 38 is also sufficient, which are formed on the upper electrodes 32, 62b and 72.

So far as at least the upper surface of the upper electrode 32, 62b or 72 is flat, diffusion of hydrogen may be prevented. When a hydrogen atmosphere is employed to form an interlayer insulating film 24 surrounding the ferroelectric capacitor 13, 63 or 73, the insulating hydrogen barrier film 36 may be necessary which coats the surface of the ferroelectric capacitor 13, 63 or 73.

Other embodiments or modifications of the present invention will be apparent to those skilled in the art from consideration of the specification and practice of the invention disclosed herein. It is intended that the specification and embodiments be considered as exemplary only, with a true scope and spirit of the invention being indicated by the following.

1-7. (canceled)

8. A non-volatile memory device including a ferroelectric capacitor, comprising:
a semiconductor substrate;
an insulating film formed on the semiconductor substrate;
a first electrode of the ferroelectric capacitor formed on the insulating film;
a ferroelectric film of the ferroelectric capacitor formed on the first electrode and having a convexo-concave surface portion;
a second electrode of the ferroelectric capacitor formed on the ferroelectric film and connected to an interconnection, the second electrode burying the convexo-concave surface portion and having a surface flatter than a surface of the ferroelectric film;
a hydrogen barrier film formed at least on a surface of the second electrode; and
an insulated gate type transistor provided in connection with the semiconductor substrate, the insulated gate type transistor having a first diffusion layer, a second diffusion layer, and a gate electrode.

9. The non-volatile memory device according to claim 8,
wherein the first ferroelectric film is a film formed by MOCVD.

10. The non-volatile memory device according to claim 8,
wherein the second ferroelectric film is a film formed by sol-gel method.

11. The non-volatile memory device according to claim 8,
wherein the hydrogen barrier film is an insulating protective film to coat at least a portion of the upper surface of the second electrode and a side surface of the ferroelectric capacitor.

12. The non-volatile memory device according to claim 11, further comprising:
an interlayer insulating film formed in a hydrogen atmosphere to adjoin and surround the hydrogen barrier film.

13. The non-volatile memory device according to claim 8,
wherein the hydrogen barrier film is a conductive film to coat at least a portion of the upper surface of the second electrode.

14. The non-volatile memory device according to claim 13, further comprising:
a plug formed in a hydrogen atmosphere to contact with the hydrogen barrier film,
wherein the plug is connected to an interconnection, the first diffusion layer is connected to a bit line, the second diffusion layer is connected to the first electrode, and the gate electrode is connected to a word line.

15. The non-volatile memory device according to claim 8,
wherein the second electrode includes a first layer and a second layer formed on the first layer, the first layer having a convexo-concave surface portion corresponding to the convexo-concave surface portion of the ferroelectric film, and the second layer being formed to bury the convexo-concave surface portion of the first layer and to have a surface flatter than that of the ferroelectric film.

16. The non-volatile memory device according to claim 15,
wherein the first ferroelectric film is a film formed by MOCVD.

17. The non-volatile memory device according to claim 15,
wherein the second ferroelectric film is a film formed by sol-gel method.

18-20. (canceled)
